(19) United States
(12) Patent Application Publication
(10) Pub. No.: US 2024/0201563 A1
(43) Pub. Date: Jun. 20, 2024

(54) ON-CHIP OPTICAL SYNTHESIZER

(71) Applicant: California Institute of Technology, Pasadena, CA (US)

(72) Inventors: Luis M. Ledezma, La Crescenta, CA (US); Alireza Marandi, Pasadena, CA (US); Robert M. Gray, Pasadena, CA (US); Benjamin K. Gutierrez, Redondo Beach, CA (US)

(73) Assignee: California Institute of Technology, Pasadena, CA (US)

(21) Appl. No.: 18/543,950

(22) Filed: Dec. 18, 2023

Related U.S. Application Data
(60) Provisional application No. 63/434,015, filed on Dec. 20, 2022.

(51) Int. Cl. G02F 1/39; H01S 5/026; H01S 5/065; H01S 5/125; H01S 5/14; H01S 5/50

(52) U.S. Cl. CPC G02F 1/39; H01S 5/0265; H01S 5/0657; H01S 5/125; H01S 5/141; H01S 5/50

(57) ABSTRACT

On-chip generation of coherent radiation, i.e. laser-like radiation, can be tuned over broad and/or hard-to-access wavelength regions in an integrated platform. Target spectral coverage is beyond what could be achieved with existing integrated laser systems.

### CROSS REFERENCE TO RELATED APPLICATIONS

This application claims the benefit under 35 U.S.C. Section 119(e) of copending and commonly assigned U.S. Provisional Patent Application Ser. No. 63/434,015, filed Dec. 20, 2022, by Luis Ledezma, Alireza Marandi, Robert M. Gray and Benjamin Gutierrez, entitled “ON-CHIP OPTICAL SYNTHESIZER,” CIT-8395-P, attorney docket 176.0219USP1, which application is incorporated by reference herein.

### STATEMENT REGARDING FEDERALLY SPONSORED RESEARCH AND DEVELOPMENT

This invention was made with government support under Grant No. FA9550-20-1-0040 awarded by the Air Force and Grant No. W911NF-18-1-0285 awarded by the US Army and Grant No. 80NMO0018D0004 awarded by NASA and Grant No. ECCS1846273 awarded by the National Science Foundation. The government has certain rights in the invention.

### BACKGROUND OF THE INVENTION

### 1. Field of the Invention

The present disclosure relates to integrated circuits comprising optical parametric oscillators.

### 2. Description of the Related Art

(Note: This application references a number of different publications as indicated throughout the specification by one or more reference numbers in brackets, e.g., [x]. A list of these different publications ordered according to these reference numbers can be found below in the section entitled “References.” Each of these publications is incorporated by reference herein.)

Widely-tunable coherent sources are desirable in nanophotonics for a multitude of applications ranging from communications to sensing. The mid-infrared spectral region (wavelengths beyond 2 μm) is particularly important for applications relying on molecular spectroscopy. Among tunable sources, optical parametric oscillators typically offer some of the broadest tuning ranges; however, their implementations in nanophotonics have been limited to narrow tuning ranges and only at visible and near-infrared wavelengths. We have already surpassed these limits in dispersion-engineered periodically poled lithium niobate nanophotonics and demonstrate ultra-widely tunable optical parametric oscillators [1, 2]. With a pump wavelength near 1 μm, we generate output wavelengths tunable from 1.53 μm to 3.25 μm in a single chip with output powers as high as tens of milliwatts. Our results represent the first octave-spanning tunable source in nanophotonics extending into the mid-infrared which can be useful for numerous integrated photonic applications. The design of such an optical parametric oscillator (OPO) is presented in FIGS. 1a, 1b, 1c, 1d and 1e.

### SUMMARY OF THE INVENTION

Described herein are devices fabricated on a microchip that can produce coherent radiation tunable over a wide portion of the electromagnetic spectrum, including the visible, near-infrared, and mid-infrared wavelength ranges, which is based on optical parametric oscillators (OPOs) augmented with certain control mechanisms.

Methods for controlling the spectral and/or temporal characteristics of the produced coherent radiation are further described. In some embodiments, the source is a diode source which is coupled to a waveguide on the chip with optimized geometry prior to any embodiment of the on-chip OPOs. In further embodiments, the cavity of the diode is extended on the chip where the diode is an external cavity laser diode. In yet further embodiments, the actuators are used to lock the OPO output to a reference on and/or off the chip. In some embodiments, a plurality of sources are used simultaneously to control the on-chip OPO. In yet further embodiments, feedback of the input source(s) alters the operation of the OPO to achieve certain advantages. In other embodiments, feedback from the OPO to the source(s) results in mode-locking of the source(s). In yet further embodiments, actuators are used to alter the source(s) on-chip prior to any embodiment of the on-chip OPO. In other embodiments, multiple embodiments of the on-chip OPO are implemented on a single chip. In some embodiments, additional nonlinear processes are implemented including but not limited to sum-frequency generation between pump and signal/idler, and second harmonic generation of signal/idler waves.

Illustrative embodiments of the present invention include, but are not limited to, the following.
1. A device, comprising:
   a photonic integrated circuit comprising:
   an optical parametric oscillator (OPO) outputting at least one of a signal or an idler in response to a pump; and
   at least one of a source for the pump, an external injection locking input, or an auxiliary resonator coupled to the OPO.
2. The device of embodiment 1, wherein the photonic integrated circuit further comprises an edge coupler, a grating coupler, or an evanescent coupler positioned to couple the source to the OPO.
3. The device of embodiment 1 wherein the source comprises a gain medium, such a semiconductor gain element, and a cavity to form a laser comprising the gain medium.
4. The device of embodiment 3, wherein at least a portion of the laser cavity is in the photonic integrated circuit coupled to the gain medium, including a configuration in which the laser cavity is positioned to receive feedback from the photonic integrated circuit into the laser cavity.
5. The device of embodiment 4, wherein the OPO comprises an output coupler coupled to output the feedback from the OPO to the gain medium and/or the laser cavity.
6. The device of embodiment 4, wherein at least a portion of the OPO is within the laser cavity.
7. The device of embodiment 4, wherein the photonic integrated circuit comprises at least one of a reflector positioned to reflect the feedback to the laser cavity, an auxiliary resonator coupled to the OPO, at least one OPO actuator coupled to the OPO for tuning the OPO, at least one auxiliary actuator coupled to the auxiliary resonator for tuning the auxiliary resonator, or a source actuator coupled to the source for tuning the pump.
8. The device of embodiment 7, wherein the reflector is a tunable reflector configurable to tune a wavelength of the feedback controlling a wavelength of the pump outputted from the source.
9. The device of embodiment 7, further comprising:
   the laser cavity comprising the reflector coupled to the OPO and the gain medium, and
   the source actuator positioned between the reflector and the gain medium and configurable to modulate the laser cavity so that the source comprises a mode-locked laser.
10. The device of embodiment 7, further comprising:
   the reflector comprising a wavelength tunable reflector, and
   the source actuator positioned between the reflector and the gain medium and/or the source actuator is coupled to the reflector,
   and the actuators can modulate a wavelength of the source so that the source comprises a CW laser.
11. The device of embodiment 3, wherein:
   the photonic integrated circuit comprises an auxiliary nonlinear region coupled between an output of the OPO and the gain medium, and
   the auxiliary nonlinear region is configured to up convert a frequency of the signal and/or the idler to form feedback outputted to the gain medium and/or the laser cavity.
12. The device of embodiment 11, wherein the OPO is configurable to output a feedback to the laser cavity that self-injection-locks the pump.
13. The device of embodiment 11, wherein the OPO is configurable to output the feedback comprising multiple modes for mode-locking the source or provide the feedback for spectrally narrowing the pump.
14. The device of embodiment 3, wherein the auxiliary resonator is coupled in the photonic integrated circuit so as to at least:
   tune a frequency of the pump,
   filter the frequency of the pump, or
   self injection lock the pump of the OPO.
15. The device of embodiment 1, wherein the auxiliary resonator is:
   resonant at a wavelength of the pump and is coupled to an additional parametric gain region or shares a parametric gain region with the OPO, or
   tuned to filter or modulate a frequency of the modes in the OPO.
16. The device of embodiment 1, wherein the auxiliary resonator comprises:
   a pump resonator pumped by the pump and having at least some overlapping modes with the OPO resonator so that at least some of the overlapping modes are enhanced and recycled in the pump resonator; and
   an electro-optical modulator coupled to the pump resonator for locking the modes of the pump resonator to the modes of the pump.
17. The device of embodiment 1, wherein the auxiliary resonator is configured in the photonic integrated circuit so as to at least:
   tune a frequency of at least one of the signal or the idler,
   filter the frequency, or
   self injection lock at least one of the signal or the idler to the OPO.
18. The device of embodiment 1, wherein the OPO comprises a main resonator coupled to at least one parametric gain region and the actuators comprise:
   one or more electro-optic modulators coupled to at least one of the main resonator, the at least one parametric gain region, or the auxiliary resonator and actuatable to tune a gain and/or frequency of oscillation of pump, the signal, and/or the idler in the resonators, or
   a heater thermally coupled to the parametric gain region so that heat output is actuatable to tune a gain and/or center frequency of at least one of the pump, the idler, or the signal outputted from the parametric gain region.
19. The device of embodiment 1 further comprising one or more of the external injection locking inputs positioned to couple a seed signal configured for injection locking the signal and/or the idler.
20. The device of embodiment 1, wherein the photonic integrated circuit further comprises additional OPOs and a switch for switching the pump to different ones of the OPOs.
21 The device of embodiment 1, further comprising a plurality of the auxiliary resonators configurable to control a frequency of the signal and/or idler in a range such that the OPO can be operated free of mode-hops.
22. The device of embodiment 1, wherein the OPO resonator is coupled to one or more of the auxiliary resonators having a different free spectral range, such that a combination of the modes of the main resonator and the auxiliary resonators selects a single mode or a set of modes that oscillate in the main resonators.
23. The device of embodiment 3, further comprising a waveguide coupling the gain medium to an input of the OPO, wherein the waveguide is configured to match a mode of the pump with a mode of the OPO.
24. The device of embodiment 1, comprising a plurality of the OPOs comprising parametric gain regions with different spectral responses, for instance through different quasi phase matching periods.
25. The device of embodiment 24, wherein inputs and the outputs of the OPOs are coupled so that the signal and/or idler at one or more of the outputs are used as the pump at one or more of the inputs and parametric gain regions in the OPOs generate the signal and/or the idler in a wavelength range from visible to infrared by selecting an appropriate combinations of the inputs and outputs.
26. The device of embodiment 1, wherein the circuit further comprises at least one nonlinear section designed for up and/or down conversion of the signal, and/or the idler, through second-harmonic generation, and/or sum-frequency generation or difference-frequency generation, which can involve the pump or an auxiliary input to the circuit for the up and/or down conversion.
27. A device, comprising:
   a photonic integrated circuit comprising:
      an optical parametric oscillator (OPO) comprising a main resonator coupled to a parametric gain region outputting a signal and an idler in response to a pump using a parametric nonlinear process; and
      at least one of a tuning circuit or a mode-locking circuit coupled to the OPO.

### BRIEF DESCRIPTION OF THE DRAWINGS

Referring now to the drawings in which like reference numbers represent corresponding parts throughout:

FIGS. 1a, 1b, 1c, 1d and 1e illustrate on-chip widely tunable parametric oscillators. FIG. 1a can produce coherent radiation tunable over an octave when pumped with a commercially available near-infrared laser. FIG. 1b shows that the OPO consists of a periodically poled section and a main resonator created with wavelength selective couplers. FIG. 1c is an image of a fabricated chip containing 16 OPOs. FIG. 1d is an optical microscope image of an individual OPO from the chip on FIG. 1c. FIG. 1e shows the OPO output wavelength as a function of pump wavelength for four of the OPOs on the same chip.

FIGS. 2a, 2b and 2c illustrate base OPOs. FIG. 2a is a base OPO implemented using a ring resonator. FIG. 2b is a base OPO implemented using a linear resonator which uses Sagnac loop reflectors at either end of the cavity. FIG. 2c is a base OPO implemented using a linear resonator which uses Bragg reflectors at either end of the cavity.

FIGS. 3a, 3b and 3c illustrate on-chip OPOs with intracavity controllers.

FIGS. 4a, 4b and 4c illustrate pump resonant on-chip OPOs.

FIGS. 5a, 5b, 5c and 5d illustrate injection locked on-chip OPOs.

FIG. 6 illustrates range extension methods.

FIGS. 7a, 7b, 7c and 7d illustrate diode integrated on-chip OPOs.

FIGS. 8a, 8b, 8c, 8d and 8e illustrate embodiments of the device which further include diode integration.

FIGS. 9a and 9b illustrate intracavity on-chip OPOs.

FIG. 10a illustrates an embodiment that includes a tunable vernier filter and FIG. 10b illustrates an embodiment that includes an additional auxiliary resonator.

FIGS. 11a and 11b illustrate cascaded systems.

FIGS. 12a and 12b illustrate mode locked operation comprising laser mode-locking 1. Two examples of a ring-resonator architecture where pulsed operation of the OPO provide strong feedback to the laser leading to laser mode locking.

FIGS. 13a and 13b illustrate mode locked operation comprising laser mode-locking 2. Two examples of a linear-resonator architecture where pulsed operation of the OPO provide strong feedback to the laser leading to laser mode locking.

FIG. 14a illustrate a Distributed Bragg reflector (DBR) laser showing a Bragg grating at the back of the device works as a wavelength selective mirror providing large feedback over a narrowband wavelength range. The cleaved output facet at the front of the device also functions as the other end of the laser cavity. A ridge waveguide, consisting of a layered structure with one or more high refractive index quantum wells, runs between the front cleaved facet and the Bragg mirror. Images by JESpencer Own work, CC BY-SA 4.0, https://commons.wikimedia.org/w/index.php?curid=34983533.

FIG. 14b illustrates the power and wavelength variation (Δλ=1−λ₀) as a function of injection current for the DBR used to pump our OPOs. As the injection current increases, the wavelength monotonically red-shifts in between blue-shift mode hops. Data courtesy of Photodigm, Inc.

FIG. 15 illustrates an estimated mode shape at the output facet of commercially available DBR laser. The manufacturer provided full-width-half-maximum divergence angles (6° for the horizontal and 28° for the vertical directions) were used to model the DBR output as a single mode elliptical beam with 3.81 μm and 0.82 μm waists.

FIG. 16 illustrates an estimated power coupling efficiency from diode laser to TFLN chip. Shown as a function of the TFLN waveguide width. The dashed black trace is the result of an overlap integral between the DBR mode from FIG. 15 and the mode of the TFLN waveguide. The continuous red trace also includes the effect of back reflections due to the difference in effective indexes between the waveguides (assuming n_{eff}≈3.5 for the DBR waveguide). Insets show TFLN mode profiles for 2.5 μm and 10 μm width

FIGS. 17a and 17b illustrate the effect of optical feedback on semiconductor lasers. Two major sources of feedback are the input and output facets of the OPO chip. The number of modes that can satisfy constructive interference (Δϕ=0) depends on the relative size of the DBR laser cavity roundtrip delay (τ_{L}), compared to the roundtrip delay of the external cavity formed by the OPO chip (τₑ).

FIGS. 18a and 18b show a DBR laser frequency as a function of injection current with optical feedback, wherein FIG. 18a is the DBR laser frequency as the current is modulated by a triangular waveform from 110 mA to 190 mA. The output is unstable with multiple modchops in distinct directions as the current changes and FIG. 18b shows after reducing the optical feedback by polishing the output facet at a 7° angle, the DBR laser frequency is stable, varying in a predictable way and with the expected blue-shifted mode hops.

FIGS. 19a, 19b and 19c show an OPO chip coupled to a DBR laser diode, wherein FIG. 19a is an image of OPO chip on test setup, with DBR laser and output cleaved multimode fiber also visible. The dashed rectangle delineates a single OPO on the chip, FIG. 19b is close-up image of the DBR laser in close-contact with the TFLN chip. Two waveguides are visible on the TFLN chip, one is the input to the OPO and the other is a straight waveguide for testing purposes, and FIG. 19c is close-up image with the laser diode above threshold. The camera can detect the scattered near-IR light at the interface between the laser and the TFLN chip.

FIGS. 20a, 20b and 20c illustrate the spectra of free-running continuous (CW) OPO driven by DBR laser diode, wherein FIG. 20a is an example output spectra for slightly different pump wavelengths around ˜1063.7 nm, at a DBR injection current of 241 mA corresponding to ˜160 mW, FIG. 20b is a closeup of the three spectra a function of frequency. The resolution bandwidth of the optical spectrum analyzer was set to ˜3.4 GHz, so different resonator modes are distinguishable. The mid-trace (green) corresponds to a signal/idler single mode pair, while the other two traces show multimode behavior, and FIG. 20c is an example of stable operation on the near-degenerate mode corresponding to the top panel of FIG. 20a; the OPO remained stable for more than 30 minutes without the use of any locking technique or environmental isolation.

FIG. 21 is a flowchart illustrating a method of making a device.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

Described herein is a device fabricated on a microchip that is based on optical parametric oscillators (OPOs). This device further includes control mechanisms and/or sources to enhance the functionality of the on-chip OPO.

### Base OPOS

OPOs are fabricated using an optical nonlinear gain section enclosed by an optical cavity. The nonlinear gain section can be implemented on-chip in lithium niobate using periodic poling, known as periodically poled lithium niobate (PPLN). The on-chip cavity can be of either a ring-type or linear-type resonator. A ring resonator relies on a waveguide, or set of waveguides connected by optical couplers, that is enclosed on itself to form a single continuous optical path. A linear resonator relies on on-chip reflectors such as Sagnac loop reflectors, Bragg reflectors, a cleaved facet with high reflectivity or any other on-chip device used to reflect electromagnetic radiation back into the same waveguide forming a bidirectional resonator. As used herein, the term “base OPO” refers to such on-chip OPOs implemented in this way.

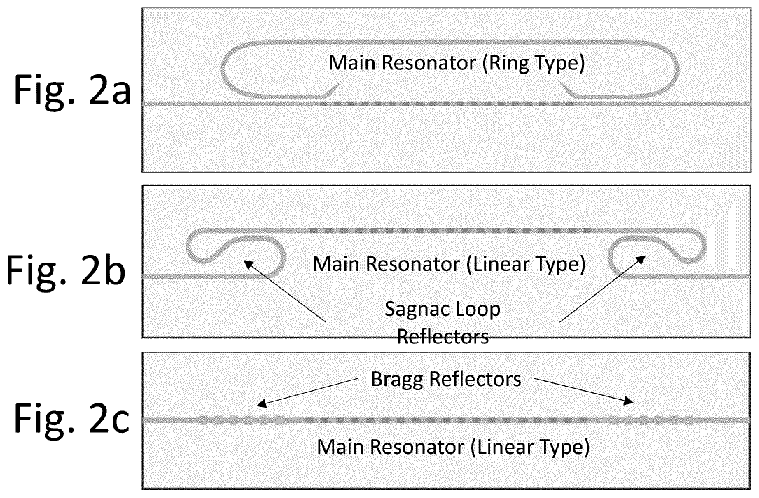

FIGS. 2a, 2b and 2c demonstrate some embodiments of the base OPO. The base OPOs are limited in their ability to control the produced coherent radiation. Changing the characteristics of this radiation in such base OPOs is limited to altering the characteristics of the resonator and PPLN sections. Such alterations are static, that is, once the chip is fabricated it is fixed and there is no way to dynamically control the coherent radiation that is produced. The only way to do so is to fabricate a new device entirely. This limits the usefulness of such base OPOs in many applications.

### Control Mechanisms (Actuators, Auxiliary Resonators, Filters, and Sources)

Embodiments of the device described herein further include control mechanisms enabling dynamic control of the base OPO. Under the term “control mechanisms” or “controllers” we define actuators, auxiliary resonators, filters and sources as follows.

As used herein, the term “actuator” refers to any electro-optic modulators (EOMs), acousto-optic modulators (AOMs), heaters, or any on-chip and/or off-chip device and/or mechanism used to dynamically change the refractive index of any portion of the device. Any combination of actuators may be used individually from each other and/or in conjunction with each other to perform certain dynamic alterations to the base OPO that allow for control over the output coherent radiation.

As used herein, the term “auxiliary resonator” refers to any linear and/or ring resonator implemented in addition to the main OPO resonator. The auxiliary resonator may be separate from the main resonator or share a portion of the waveguide attached to the main resonator.

As used herein, the term “filter” refers to any combination of resonators, couplers, or integrated components that enable spectral selectivity.

As used herein, the term “source” refers to any on-chip and/or off-chip device capable of producing electromagnetic radiation which is then used as an input to the on-chip OPO. This radiation may be coherent or incoherent. This radiation may be pulsed radiation, continuous radiation, or some combination of the two. The source may be further coupled to the chip using free-space methods such as end-fire coupling to a chip facet or grating coupler and/or direct coupling techniques such as butt coupling to the chip facet. The source may be a diode source that is butt-coupled to a waveguide which is tapered to an optimized geometry.

### Illustrative Embodiments

a. On-Chip OPOs with Intracavity Controllers

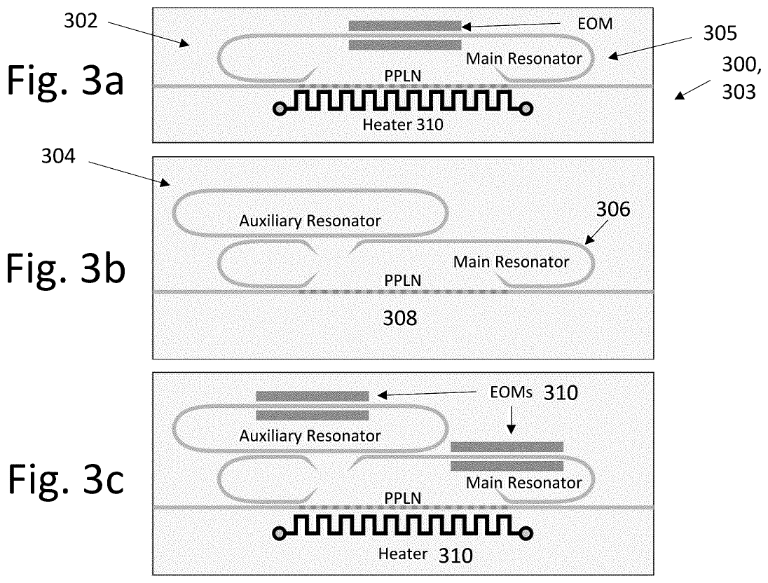

In one embodiment, a device 300 as described herein may implement a base OPO which further includes intracavity controllers. There may be one or more than one intracavity controller. The controllers may operate separately and/or simultaneously. In one embodiment illustrated in FIG. 3a, an EOM 310 is implemented in the main resonator 306 and a heater 310 is implemented along the PPLN section. In addition to tuning the resonators modes, the intracavity actuators can also be used to actively lock the operation of the OPO 302. This locking may be performed just by measuring the operation of the OPO itself or comparing its operation with an external reference. The external reference includes a passive cavity, either on the same chip or off chip, or atomic or molecular transitions. Moreover, the generated output of the OPO can be additionally up or down converted on the same chip to match the desired wavelength.

The on-chip OPO can be combined with an auxiliary resonator, or multiple auxiliary resonators, which have different free-spectral ranges (FSR) compared to the main resonator. The coupling to this resonator can be conservative or dissipative (where additional open ports exist). The additional resonator can be of different types, for instance a ring resonator or a linear resonator. Combinations of the modes of the secondary resonator and the main resonator affect the operation of the OPO. This combination can be set in a way that only a single mode (or a set of desired modes) of the main resonator oscillates. The OPO operation principle of such a design can be similar to the use of an intracavity etalon in the free-space OPOs.

In one embodiment, the base OPO further includes an auxiliary resonator 304 that is a ring resonator conservatively coupled to the main resonator (FIG. 3b). In this embodiment, the overlap of the spectral modes between the main and auxiliary resonators can result in either single mode operation of the OPO or a selective multimode operation of the OPO. Another related embodiment further includes intracavity actuators 310 in both the main and auxiliary resonators 304 (FIG. 3c). Thermal and electro-optic actuators are implemented for coarse and/or fine tuning of the oscillation frequency. A heater is used to adjust the parametric gain center frequency for broad-tunability. Electro-optic modulators on the main and secondary resonators are used for fine-tunability of the oscillating frequency mode. These actuators can be used for locking the OPO output to a reference on or off chip.

b. Pump Resonant On-Chip OPOs

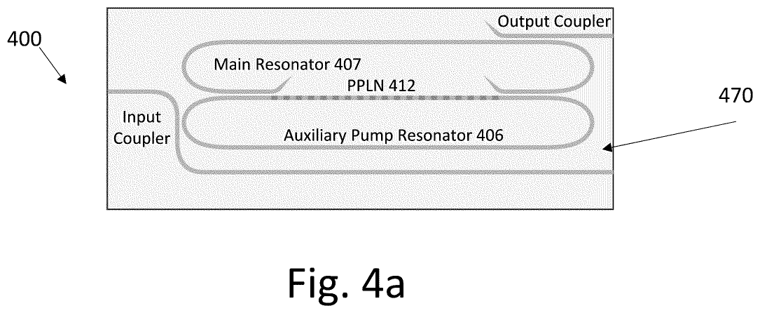

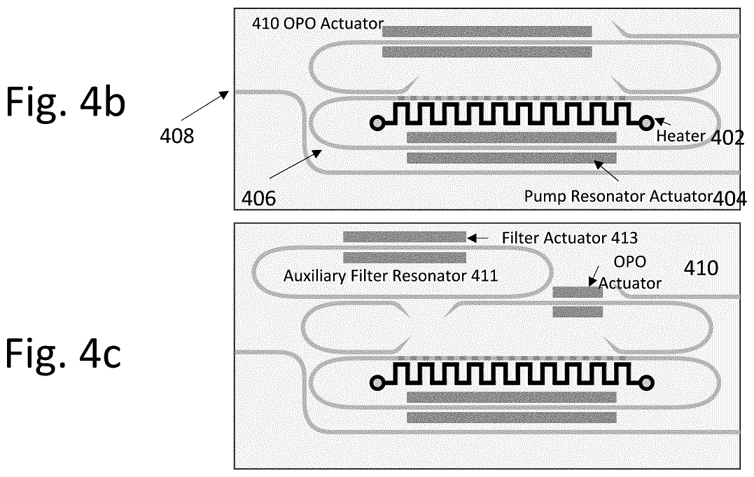

In other embodiments illustrated in FIGS. 4a, 4b and 4c, a device 400 as described herein may implement a base OPO which further includes an auxiliary resonator that is resonant at the pump wavelength. In one embodiment, the auxiliary resonator 406 is a ring resonator that shares the PPLN section 412 of the main resonator 407 (FIG. 4a). In this embodiment, the pump wavelength is further coupled to the auxiliary resonator 406 (via a conservative coupler). This enables resonant enhancement of the pump field for the OPO cavity, which affects the threshold and efficiency of the on-chip OPO. In another embodiment, the device further includes actuators 410 in the main resonator, auxiliary resonator, and along the PPLN section (FIG. 4b). This enables resonant enhancement of the pump field for the OPO cavity, which can be controlled using an actuator 404 in the pump resonator. In another embodiment, the device further includes an additional auxiliary resonator 411 coupled to the main resonator to act as a spectrally selective filter. The device may further include actuators 413 in this auxiliary resonator to tune the resonant frequency modes (FIG. 4c). In another embodiment, the auxiliary resonator can also be combined with additional OPO resonators.

c. Injection Locked On-Chip OPOs

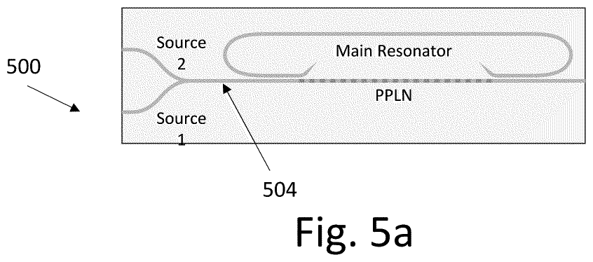

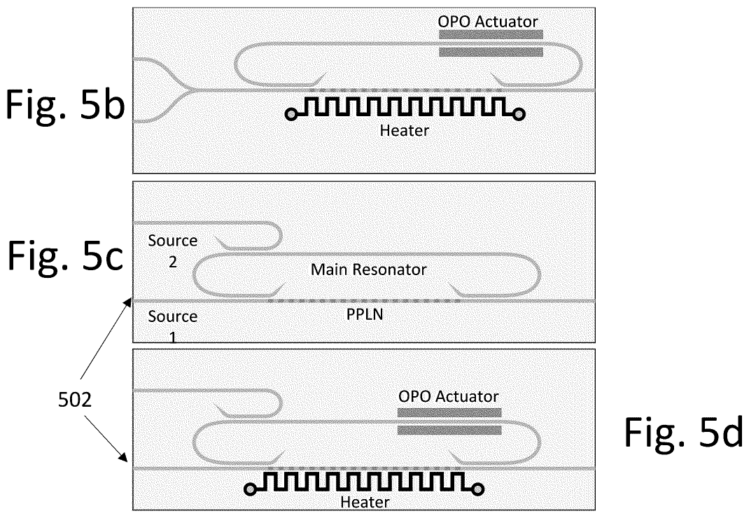

FIGS. 5a, 5b and 5c illustrate that more than one source may be used simultaneously to injection lock the operation of the device 500. In some embodiments, the two sources (source 1 and source 2) are combined into a single waveguide 504 before being injected into the device (FIG. 5a, FIG. 5b). In another embodiment, the sources 502 are injected into the device 500 at separate locations (FIG. 5c, FIG. 5d). In either case, the additional source acts to seed the operation of the device to lock the output coherent radiation to a specific operating condition. Such injection-locked techniques allow for the transfer of the coherence properties of the source(s) to the output coherent radiation of the device.

d. Range Extension Methods

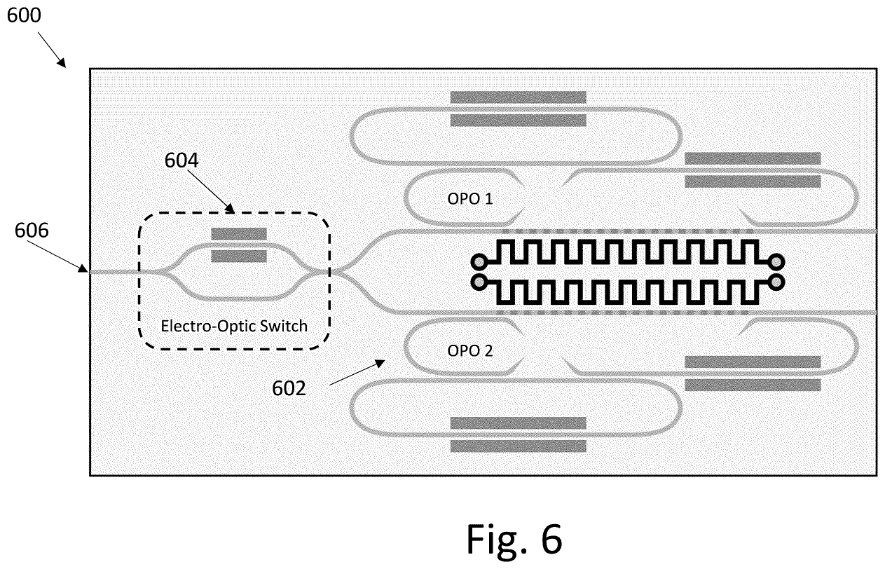

The OPO tuning range can be greatly extended by using multiple OPOs with the different quasi-phase matching periods. These can be driven with the same pump laser by using an electro-optic switch integrated on the same chip 600, as illustrated in FIG. 6. In one embodiment, two on-chip OPOs 602 are driven by a single source 606 which includes an electro-optics switch 604 to route the pump laser to either of the on-chip OPOs 602 (FIG. 6).

Additionally, the tuning range of the signal/idler can be used to access new wavelengths through second-harmonic generation on the same chip. Similarly, sum-frequency generation can be used to combine the tunable signal/idler waves with the pump wave to generate wavelengths much shorter than the pump, including the visible wavelength range. All these processes can be implemented on the same chip.

e. Diode Integrated On-Chip OPOs

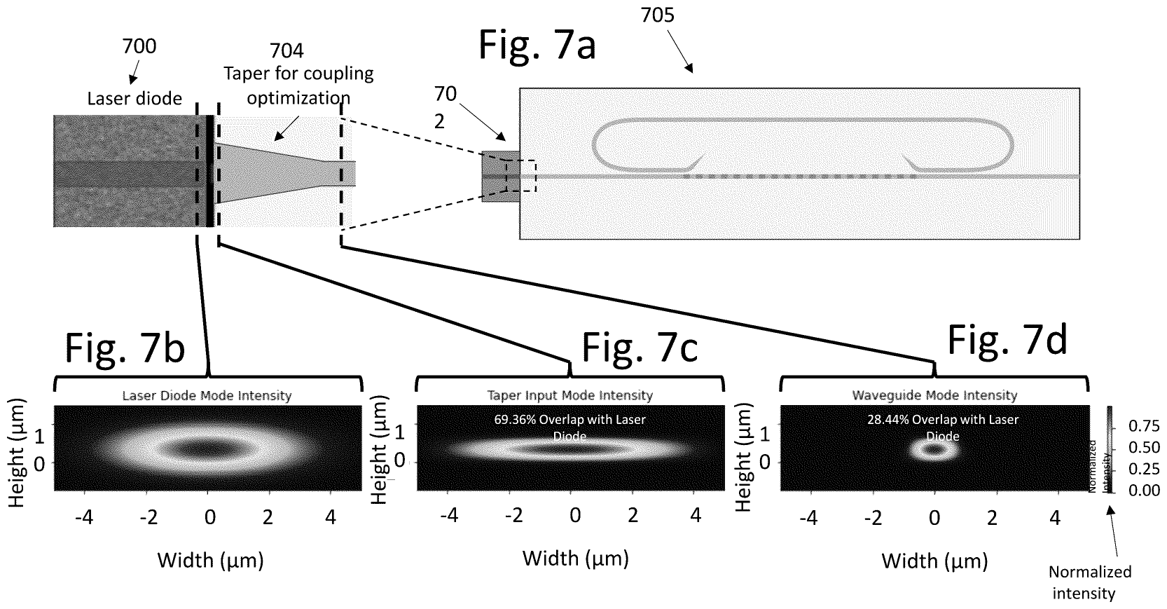

In yet further embodiments, a device as described herein may further include integration with a semiconductor laser chip (such as a laser diode 700, or a semiconductor gain element) to achieve a fully integrated source, as illustrated in FIGS. 7a, 7b, 7c and 7d. The semiconductor chip can act as a stand-alone pump laser, i.e. its operation is independent of the circuitry on the OPO chip, and/or be affected by circuit elements on the OPO chip 705. All embodiments of the device, including the base OPOs, constitute new embodiments of the device when further incorporating diode integration. In one embodiment, a semiconductor chip (laser diode) is butt-coupled 702 with an on-chip base OPO. Some embodiments further include additional components to optimize the coupling of light from the diode to the OPO chip, including a tapered waveguide 704 (FIG. 7).

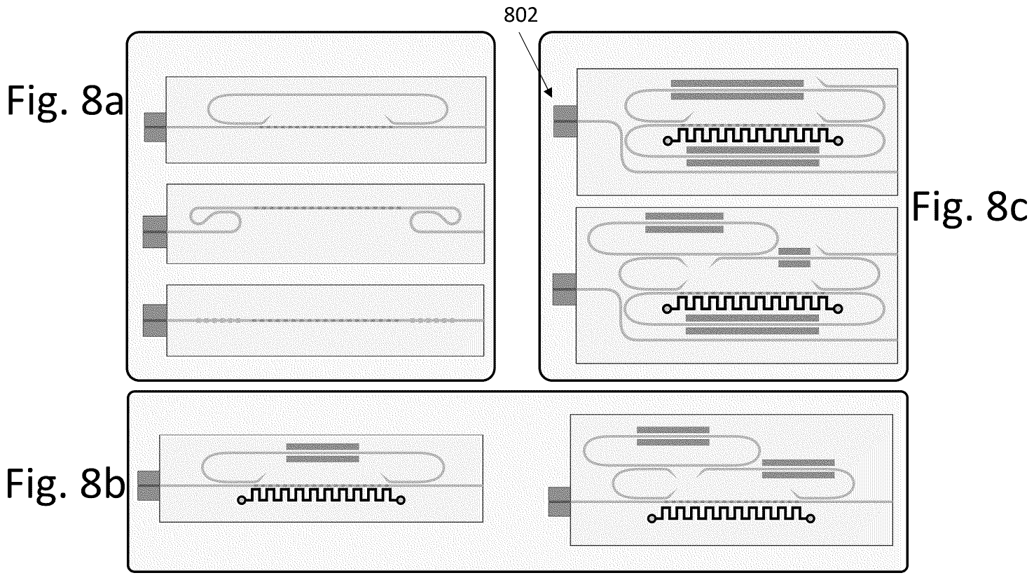

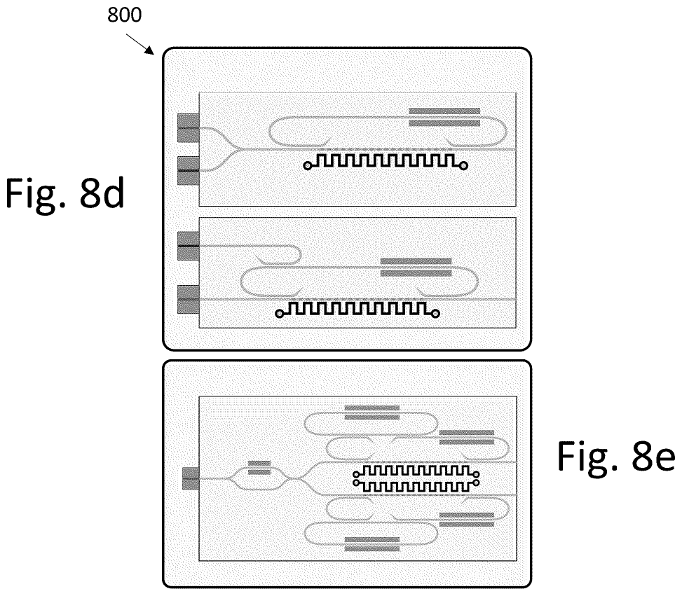

FIGS. 8a, 8b, 8c, 8d and 8e demonstrate embodiments of the device 800 which further include diode 802 integration.

f. Intracavity On-Chip OPOs

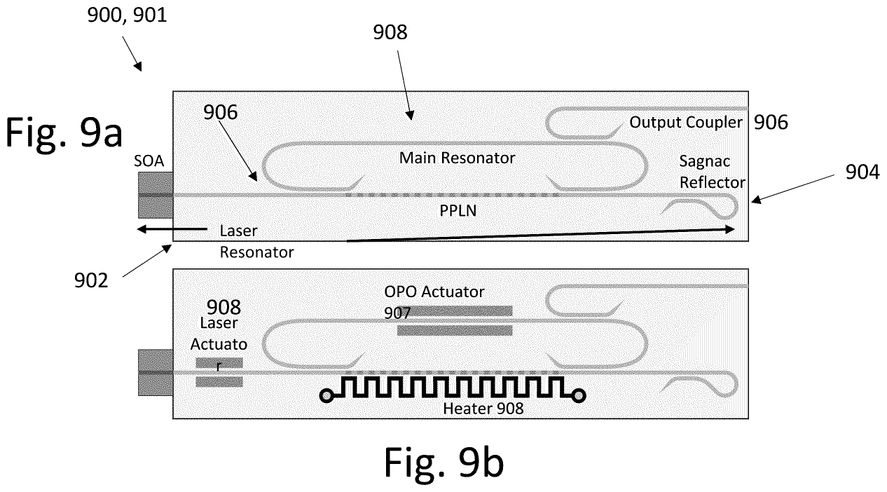

Diode integration may also enable enhanced operational capabilities. For example, if the diode is a semiconductor optical amplifier (SOA), the laser cavity 902 can be extended to the OPO chip 901 where a distributed Bragg reflector, Sagnac loop reflector 904 or any other reflecting components define the laser operation, as illustrated in FIGS. 9a-9b. An embodiment of the device 900 may be placed inside the laser cavity of an external cavity laser diode resulting in an intracavity OPO. The OPO chip can provide feedback to the laser gain chip, in which the laser cavity is external to the semiconductor chip. The feedback mechanism can be through some reflection mechanism. The reflection mechanism can be placed after the OPO and/or before the OPO. In one embodiment of the device, an SOA is butt-coupled to a waveguide that acts as the input for another embodiment of the device, which further includes a Sagnac loop reflector 904 placed after the OPO (FIG. 9a). Another related embodiment further includes actuators 907, 908 to tune the device (FIG. 9b). The laser actuator may also be used to mode-lock the laser cavity resulting in an intracavity mode-locked OPO. Output coupler 906 can also be included.

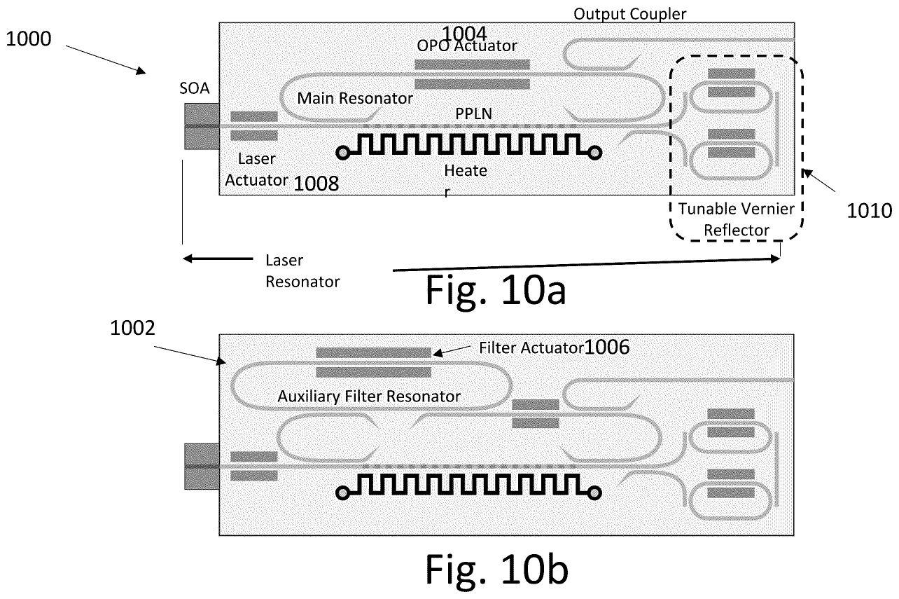

In another embodiment, the device further includes a tunable vernier filter 1010 incorporated in the Sagnac loop mirror to form a tunable reflector (FIG. 10a). This tunable reflector may act to control the pump laser wavelength, imparting another control mechanism for the OPO. In another embodiment, the device further includes an additional auxiliary resonator 1002 coupled to the main resonator to act as a spectrally selective filter, which may further include actuators 1006 in this auxiliary resonator to tune the resonant frequency modes (FIG. 10b).

g. Cascaded Systems

In some embodiments, the source may further include control mechanisms which alter the source radiation before being injected into any embodiment of an on-chip OPO.

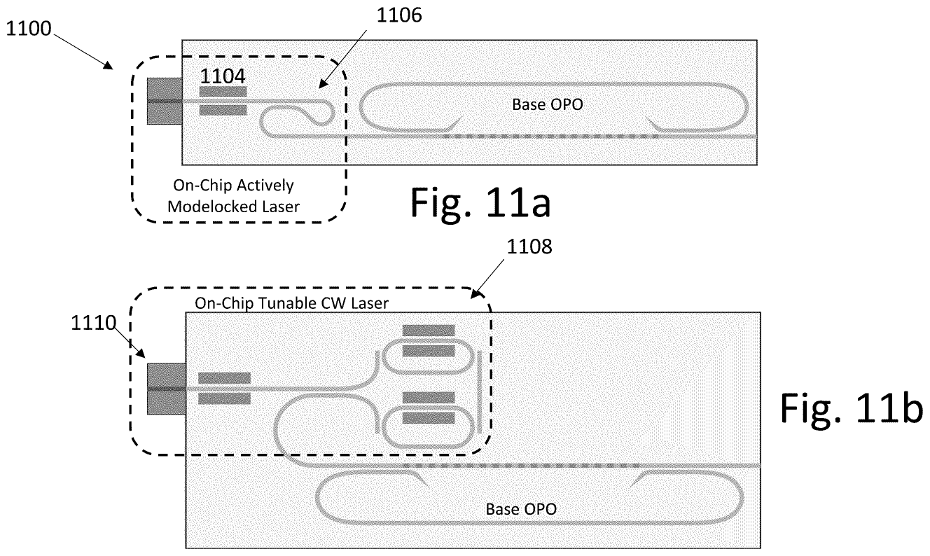

In this way, the source may be dynamically controlled resulting in the effective dynamic control of the on-chip OPO. In one embodiment, a semiconductor optical amplifier (SOA) is butt-coupled to a waveguide on the chip which implements a Sagnac loop reflector, forming an external cavity laser. FIG. 11a illustrates EOMs 1104 are then placed before the loop reflector 1106 and modulated at the free-spectral range of the external cavity laser diode to form an on-chip mode locked laser. The output of this source is then used as an input to any embodiment of an on-chip OPO. This embodiment of the device 1100 is then formed by an on-chip mode-locked laser cascaded by an on-chip OPO (FIG. 11a). In another embodiment illustrated in FIG. 11b, an SOA is then butt-coupled to a waveguide with a Sagnac loop reflector that implements a tunable vernier filter 1108. In this embodiment, the tunable vernier filter is realized by two auxiliary ring resonators placed inside the loop reflector which are tuned using EOMs. The output of this source is then used as an input to any embodiment of an on-chip OPO. This embodiment of the device is then formed by a tunable CW laser cascaded by an on-chip OPO (FIG. 11b).

In another embodiment, a laser diode is butt-coupled to a waveguide which further implements intensity and phase modulators with a dispersion compensating section of the waveguide forming an on-chip electro-optic frequency comb. Any embodiment of the on-chip OPO is then cascaded afterward. This embodiment of the device is then formed by an on-chip electro-optic frequency comb cascaded by an on-chip OPO.

h. Mode Locked Operation

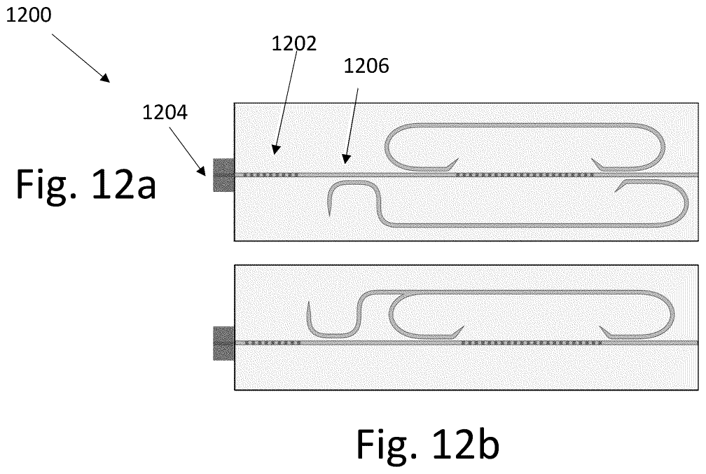

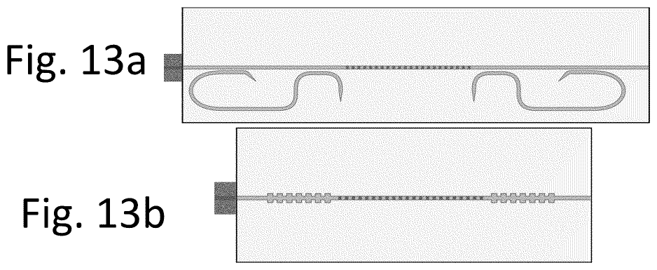

The device described herein may also include feedback to the source(s) that act to mode-lock the source itself. The feedback to the laser can also be provided at least partly through the OPO cavity. Embodiments of a device 1200 are shown in FIGS. 12a and 12b. In these configurations, the strength of the feedback to the cavity depends on the strength of nonlinearity in the OPO, for instance, the conversion efficiency of the OPO. When the OPO conversion efficiency is high, the converted wavelength can be fed back to a poled region 1202 for up-conversion before going into the laser 1204. In such a configuration, the better the OPO operation, the stronger the feedback to the laser, and hence the laser is expected to self-lock to the best operation mode. This operation mode can be multi-mode, where mode-locking is expected to happen. Apart from mode-locking, the nonlinear feedback mechanism to the OPO can also lead to spectral narrowing of the laser to match the OPO required wavelength range. In some embodiments, the feedback can also be provided using linear resonators on the same OPO chip. Examples of such extended resonators are shown in FIGS. 13a and 13b.

### Example: Laser Diode Pumped OPO

a. Introduction

There are several challenges associated with driving on-chip OPOs directly by small lasers. The most urgent one is the large coupling loss exhibited by conventional OPOs, which typically exceeded 10 dB when coupling from free-space to on-chip waveguides. As an example, an OPO having a peak power threshold of ˜30 mW translates to more than 300 mW of off-chip CW power, which, assuming the same coupling loss, is just enough to reach threshold. However, the large input coupling loss is a linear problem that can be solved by optimizing the mode overlap between the incoming pump beam and the nanophotonic waveguide. In this example, such optimization is described for the case in which the pump is a compact semiconductor laser diode.

A second challenge is that laser diodes are susceptible to optical feedback [4]. Directly butt-coupling a laser diode to a nanophotonic chip would provide back reflections at every interface, leading to potential instabilities. Indeed, previous efforts to pump table-top χ⁽²⁾ OPOs with laser diodes have required using bulky isolators [5], [6] that are not compatible with integrated photonics. This issue is resolved herein by experimentally showing that the main problem comes from reflections at the output facet of our chips, and that by decreasing those reflections, the stability of the diode laser can be improved enough to produce stable optical parametric oscillation for tens of minutes without any active locking system.

b. DBR Laser

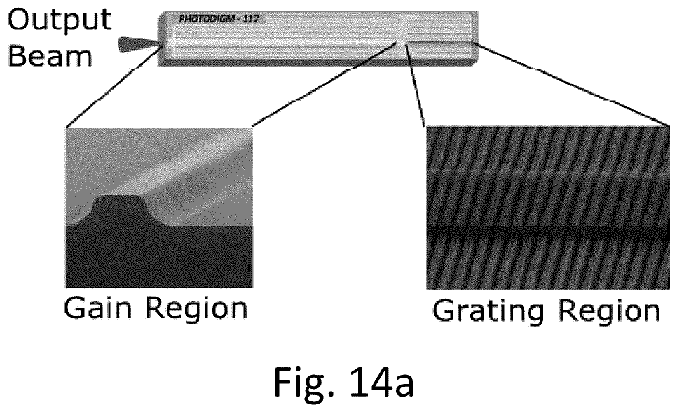

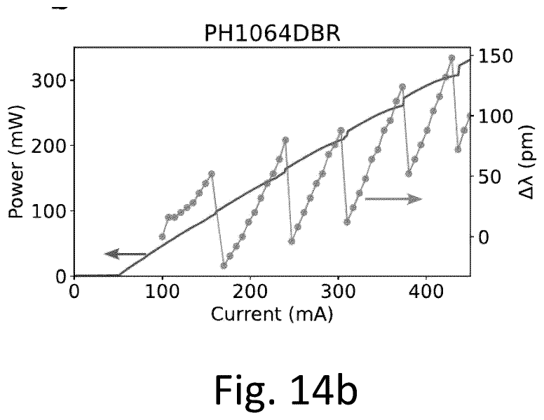

A distributed Bragg reflector (DBR) laser consists of a single spatial mode waveguide with a gain region and a passive Bragg grating region (FIG. 14a). The gain region has multiple epitaxial layers forming one or more quantum wells that are electrically pumped through current injection. The Bragg grating region forms one end of the laser cavity providing a high reflection within a narrow spectral bandwidth. The other end of the laser cavity is provided by a cleaved facet that typically includes an anti-reflection coating and serves as the output of the laser. The output beam is usually nearly diffraction limited [3].

The output wavelength of a DBR laser changes with output power and injection current as shown in FIG. 14b for the commercial DBR we use to pump our OPOs (PH1064DBR—Photodigm Inc. [3]). As the injection current is increased, the temperature of the gain region raises causing thermal expansion and a corresponding red-shift of the output wavelength. The temperature of the Bragg region does not vary significantly with injection current into the gain region. Therefore, the DBR reflectivity bandwidth is mainly a function of the global device temperature and not the injection current. After the output mode has red-shifted a certain amount due to the temperature increase, another mode will be favored by the combination of gain and reflectivity and a blue-shift mode-hop will occur. This mode hop will be typically equal to a single free spectral range of the laser cavity. For instance, FIG. 14b shows blue shift mode hops of ˜20 GHz, corresponding to a cavity length ˜1.5 mm. In principle, this tuning behavior allows for a monotonic increase in the output power at a fixed wavelength by careful control of the device temperature.

c. Input Coupling Optimization

The commercial DBR laser provides a diffraction-limited beam with divergence angles, at full-width-half-maximum (FWHM) power, of Θₓ=6° for the horizontal direction and Θ_{y}=28° for the vertical direction. This corresponds to a cylindrical

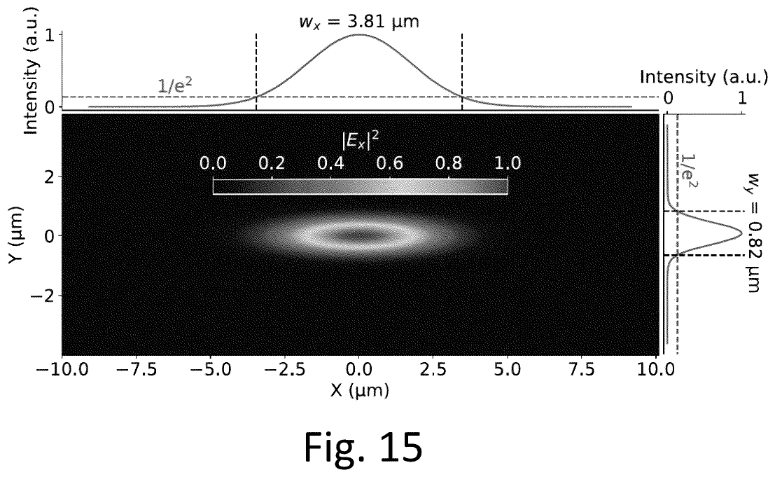

Gaussian beam, with horizontal and vertical waists of wₓ=λ\sqrt{2 ln 2}/π/Θₓ=3.81 μm, and w_{y}=λ\sqrt{2 ln 2}/π/Θ_{y}=0.82 μm, at λ=1064 nm. This estimated mode is illustrated in FIG. 15.

The power coupling coefficient between the laser and the TFLN waveguide can be written as γ=γ_{R}γ_{O}, where γ_{R} is the Fresnel power transmission coefficient and γ_{O} is a modal overlap integral. For simplicity, any potential air gap between the DBR facet and the TFLN chip facet is ignored here. Assuming that the waveguide facets are orthogonal to the propagation direction, the Fresnel transmission coefficient due to effective index differences between both waveguides is simply

$${γ}_{R} = 1 - {\vert \frac{{n}_{LN} - {n}_{DBR}}{{n}_{LN} + {n}_{DBR}} \vert}^{2} ,$$

where n_{LN} and N_{DBR} are the effective indexes of the TFLN and DBR waveguides. We assume n_{DBR}˜3.32 for the AlGaAs DBR waveguide [7], leading to γ_{R}≈95%.

The modal overlap γ_{O} is given by [8],

$${γ}_{O} = \frac{( \int {E}_{LN} \times {H}_{DBR}^{*} \cdot dS ) ( \int {E}_{DBR} \times {H}_{WG}^{*} \cdot dS )}{( \int {E}_{LN} \times {H}_{LN}^{*} \cdot dS ) ( \int {E}_{DBR} \times {H}_{DBR}^{*} \cdot dS )} ,$$

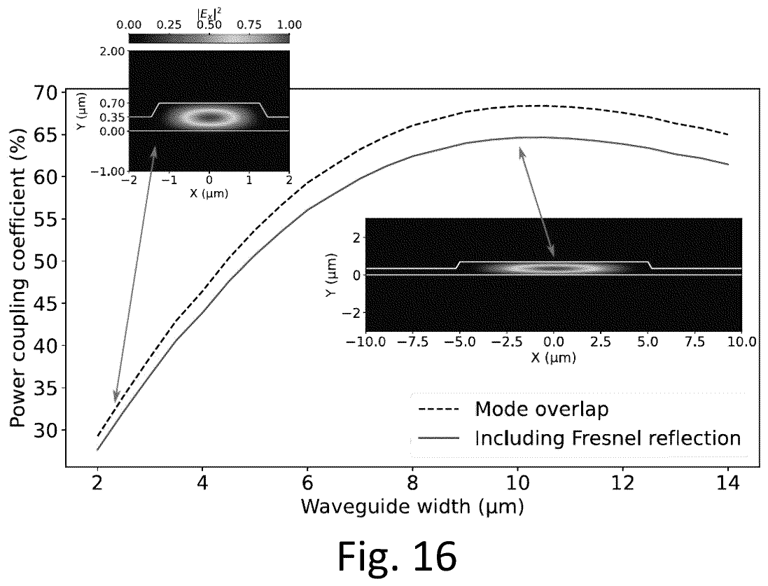

and it is real for lossless waveguides. The result of this overlap integral, as a function of the TFLN waveguide width, is shown in the dashed black trace of FIG. 16. Also shown is the total power coupling efficiency γ=γ_{R}γ₎ (continuous red trace). For this example, the waveguides are chosen to be 10-μm wide at the facet, where this analysis shows a coupling efficiency close to 65%. A 100-μm-long adiabatic taper is used to transform the input 10-μm-wide waveguide into the 2.7-μm-wide waveguide at the input coupler of the OPO.
   d. Back Reflection Minimization

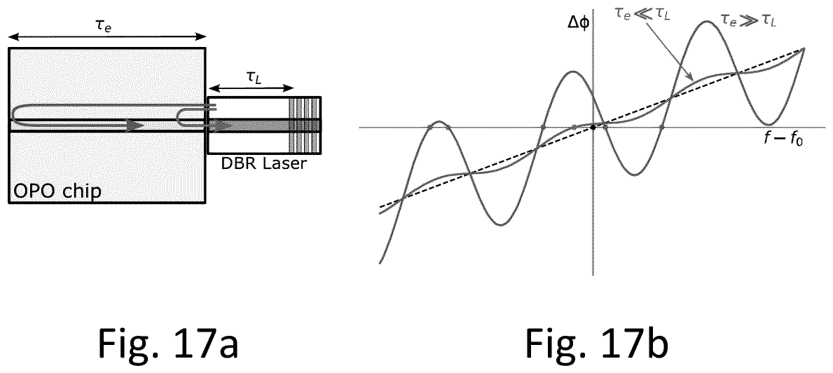

All types of laser diodes are susceptible to external optical feedback [4], [9]. The effect can vary from unstable behavior and frequent mode hops, to line broadening or narrowing effects. In our case, the two major sources of optical feedback to the pump laser come from the two OPO chip facets (see FIG. 17a). We can broadly understand the effect of each facet as follows. The input facet is in close proximity to the DBR laser facet, hence its main effect is to provide a reflection coefficient Rᵢ=|Rᵢ|exp (iϕᵢ), while producing minimal changes on the free spectral range of the laser. The magnitude of the reflection |Rᵢ| can cause changes in the threshold and linewidth of the laser output, but will not change the number of spectral modes going above threshold. In contrast, the larger cavity formed with the output facet of the OPO chip can significantly reduce the free-spectral range of the laser allowing several modes to experience significant gain and go above threshold.

A more rigorous analysis can be made that includes the back-action of laser frequency on threshold gain and effective index [4]. This leads to a change in roundtrip phase (modulo 2π) of

Δϕ=(ω−ω₀)τ_{L}+κₑ\sqrt{1+α²} sin(ωτₑ+arctan α)
where ω₀ is the oscillation frequency without external feedback, κₑ is a constant that depends on the ratio of the external cavity reflection and the DBR laser reflection without external feedback, and α is the phase-amplitude coupling parameter from semiconductor laser theory [10]. A plot of Δϕ is shown in FIG. 17b for the cases of no-feedback (dashed line), short external cavity feedback (τₑ<<τ_{L}), and long external cavity feedback (τₑ>>τ_{L}). The zero crossings indicate modes that will satisfy the positive feedback roundtrip condition.

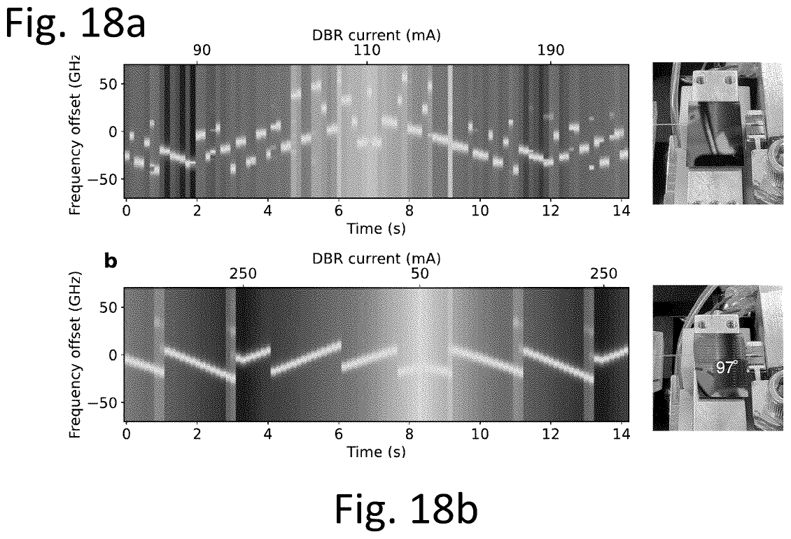

This theoretical analysis suggests that reflection from the output facet could play an important role on the stability of the DBR laser. In FIG. 18a, we show the measured spectra of the DBR laser diode as the injection current is swept and after going through a test waveguide on the OPO chip. A discontinuous tuning with frequent mode hops is observed, including regions of multimode operation. FIG. 18b shows the same measurement repeated after polishing the output facet at a 7° angle in order to reduce the magnitude of the reflections. The tuning is now monotonic except for the expected ˜20 GHz blue shift mode hops. In other examples, chips can have an output waveguide that meets the facet at an angle of at least 7°.

e. Working Example: Free-Running OPO Results

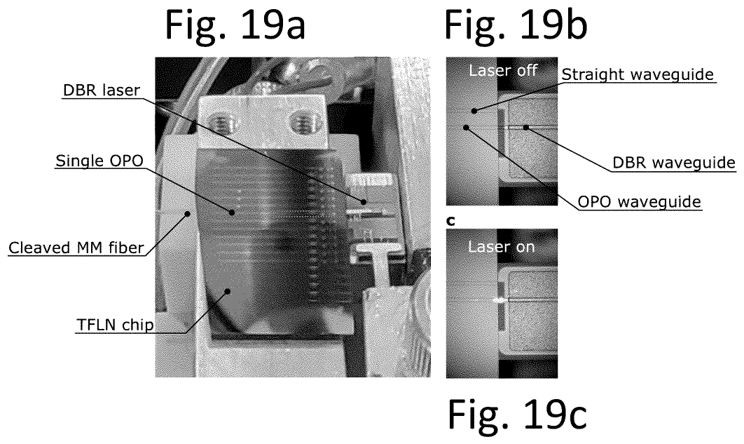

An image of the OPO chip in the test setup along with the DBR laser is shown in FIG. 19a. The OPO chip sat on a thermoelectric cooler (TEC) and we used a cleaved multimode fiber to collect the output. There were 17 OPOs on this single chip, and the red dashed line in FIG. 19a highlights a single ˜7-mm-long and ˜0.5-mm-wide OPO. FIGS. 19b and 19c show a close-up image of the DBR laser in close contact with the OPO input waveguide. Scattered 1 μm light for the laser above threshold was detected by the camera.

The OPO went above threshold at ˜120 mA, which corresponds to ˜50 mW according to the DBR laser datasheet (see FIG. 14b). As the current was increased, several oscillation peaks were observed on a 2 μm photodetector. The peaks were expected as the DBR laser wavelength is also changing when the current increases so different signal/idler pairs go into and out of resonance.

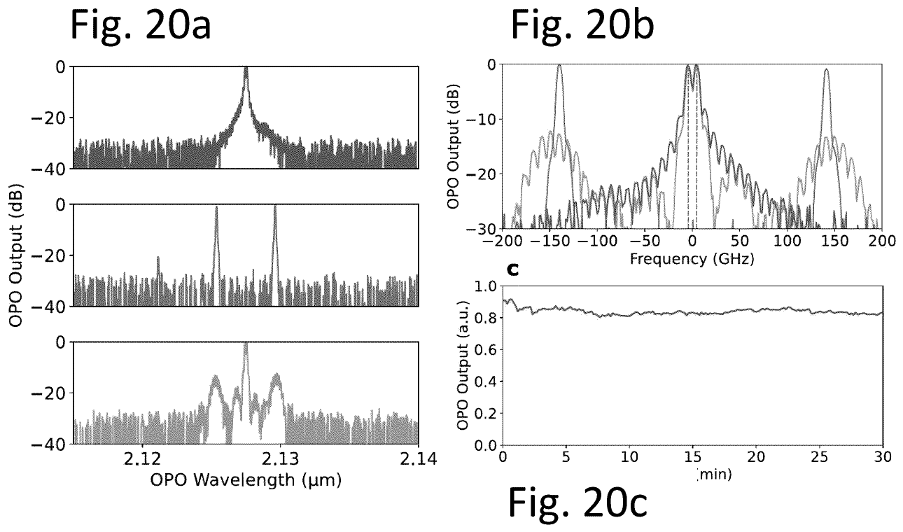

FIG. 20a shows examples of three different spectra for operation at roughly three times above threshold. This OPO could operate in a single mode signal/idler pair (middle panel in FIG. 20a), or in multimode regimes (top and bottom panels in FIG. 20a). The close-up shown in FIG. 20b has enough spectral resolution to reveal the resonator modes with ˜9.5 GHz free spectral range. This on-chip OPO demonstrated a remarkable advantage with respect to table-top implementations by oscillating continuously for more than 30 minutes, without mode hops, and without the use of any stabilization or locking techniques (FIG. 20c).

f. Possible Modifications

The results shown in this example already show the feasibility of having a compact laser source capable of replacing several individual laser diodes. The tuning range shown here, although sufficient for many applications, can be extended by using a diode pump that can be tuned over more than 10 nm, e.g., sampled grating DBR (SGDBR) designs, which include a gain section, a phase section, and front and back SGDBR mirrors [11]. Preliminary results show tuning ranges of more than 30 nm around a 1030 nm wavelength [12]. Another alternative is to harness the optical feedback from the TFLN chip to produce a tunable pump starting from a semiconductor gain chip [1]. Such pump can be integrated on the same chip as the OPO, and be tunable over the entire semiconductor gain bandwidth, and so it also inherently solves any issues related to optical feedback instabilities.

In some examples, continuous tuning of the OPO outputs may require a complex algorithm in order to exploit the interplay between all the tuning variables in a doubly-resonant OPO. An alternative would be the use of singly-resonant OPOs if all the trade-offs among threshold, tunability, and output power are found to be beneficial, as may be the case for pulsed applications.

Applications requiring single spectral modes with high coherence would need a modified OPO design. For instance, an additional resonator can be added in other to increase the effective free spectral range and limit oscillation to a single mode. An electro-optic modulator on the additional resonator would enable hopping between adjacent longitudinal modes of the main resonator [13]. Continuous mode-hop-free tuning of such nested resonators can also be achieved by a coordinated shifts in both resonators [14].

OPOs offer a large number of options in terms of coherence and frequency stabilization due to the different frequencies involved and potential for additional χ⁽²⁾ processes like sum-frequency generation. The OPO outputs can be stabilized directly to a reference cavity achieving a few kilohertz of relative stability over hours [15]. They can also be absolutely locked to atomic transitions, for instance, in Ref. [16], the OPO signal at 852 nm was locked to a hyperfine transition of Cs over several minutes. Such method could be extended to the infrared, for instance, using the same Cs transition to lock a signal at 1704 nm trough frequency doubling.

In summary, the results in this example have shown that on-chip OPOs can be pumped directly by compact semiconductor lasers without the need for additional bulky components like high power amplifiers or isolators, thus enabling the fully integrated, widely tunable, optical sources as described herein.

g. References

The following references are incorporated by reference herein.
[1] M. Li, L. Chang, L. Wu, J. Staffa, J. Ling, U. A. Javid, S. Xue, Y. He, R. Lopez-rios, T. J. Morin, H. Wang, B. Shen, S. Zeng, L. Zhu, K. J. Vahala, J. E. Bowers, and Q. Lin, “Integrated Pockels laser,” Nature Communications, vol. 13, no. 1, p. 5344, Sep. 2022, ISSN: 2041-1723. DoI: 10.1038/s41467-022-33101-6.
[2] M. Zhang, B. Buscaino, C. Wang, A. Shams-Ansari, C. Reimer, R. Zhu, J. M. Kahn, and M. Lončar, “Broadband electro-optic frequency comb generation in a lithium niobate mirroring resonator,” Nature, vol. 568, no. 7752, pp. 373-377, Apr. 2019, ISSN: 1476-4687. Dor: 10.1038/s41586019-1008-7.
[3] Photodigm Inc., PH1064DBR Series, www.photodigm.com.
[4] K. Petermann, Laser Diode Modulation and Noise. Springer Science & Business Media, Apr. 1991, ISBN: 978-0-7923-1204-8.
[5] I. D. Lindsay, G. A. Turnbull, M. H. Dunn, and M. Ebrahimzadeh, “Doubly resonant continuous-wave optical parametric oscillator pumped by a single-mode diode laser,” Optics Letters, vol. 23, no. 24, pp. 1889-1891, Dec. 1998, ISSN: 1539-4794. Dor: 10.1364/0L.23.001889.
[6] A. J. Henderson, P. M. Roper, L. A. Borschowa, and R. D. Mead, “Stable, continuously tunable operation of a diode-pumped doubly resonant optical parametric oscillator,” Optics Letters, vol. 25, no. 17, pp. 1264-1266, Sep. 2000, ISSN: 1539-4794. DOI: 10.1364/OL.25.001264.
[7] M. Achtenhagen, N. V. Amarasinghe, L. Jiang, J. Threadgill, and P. Young, “Spectral properties of high-power distributed bragg reflector lasers,” Journal of Lightwave Technology, vol. 27, no. 16, pp. 3433-3437, Aug. 2009, ISSN: 1558-2213. DOI: 10.1109/JLT. 2008.2005848.
[8] A. W. Snyder and J. D. Love, Optical Waveguide Theory (Science Paperbacks 190). London ; New York: Chapman and Hall, 1983, ISBN: 978-0-41209950-2.
[9] J. Mork, B. Tromborg, and J. Mark, “Chaos in semiconductor lasers with optical feedback: Theory and experiment,” IEEE Journal of Quantum Electronics, vol. 28, no. 1, pp. 93-108, Jan. 1992, issn: 1558-1713. DoI: 10.1109/3.119502.
[10] C. Henry, “Theory of the linewidth of semiconductor lasers,” IEEE Journal of Quantum Electronics, vol. 18, no. 2, pp. 259-264, Feb. 1982, ISSN: 15581713. DOI: 10.1109/JQE. 1982.1071522.
[11] P. A. Verrinder, L. Wang, J. Fridlander, F. Sang, V. Rosborough, M. Nickerson, G. Yang, M. Stephen, L. Coldren, and J. Klamkin, “Gallium arsenide photonic integrated circuit platform for tunable laser applications,” IEEE Journal of Selected Topics in Quantum Electronics, vol. 28, no. 1, pp. 1-9, 2021.
[12] P. A. Verrinder, L. Wang, J. Fridlander, F. Sang, V. Rosborough, M. Nickerson, G. Yang, M. Stephen, L. Coldren, and J. Klamkin, “Gallium Arsenide Photonic Integrated Circuit Platform for Tunable Laser Applications,” IEEE Journal of Selected Topics in Quantum Electronics, vol. 28, no. 1: Semiconductor Lasers, pp. 1-9, Jan. 2022, ISSN: 1558-4542. DOI: 10.1109/JSTQE . 2021.3086074.
[13] D. J. M. Stothard, I. D. Lindsay, and M. H. Dunn, “Continuous-wave pump-enhanced optical parametric oscillator with ring resonator for wide and continuous tuning of single-frequency radiation,” Optics Express, vol. 12, no. 3, pp. 502-511, Feb. 2004, ISSN: 1094-4087. Dor: 10.1364 OPEX.12.000502.
[14] P. Groß, I. D. Lindsay, C. J. Lee, M. Nittmann, T. Bauer, J. Bartschke, U. Warring, A. Fischer, A. Kellerbauer, and K.-J. Boller, “Frequency control of a 1163 nm singly resonant OPO based on MgO:PPLN,” Optics Letters, vol. 35, no. 6, pp. 820-822, Mar. 2010, ISSN: 1539-4794. DoI: 10.1364/OL.35.000820.
[15] O. Mhibik, T.-H. My, D. Pabœuf, F. Bretenaker, and C. Drag, “Frequency stabilization at the kilohertz level of a continuous intracavity frequency doubled singly resonant optical parametric oscillator,” Optics Letters, vol. 35, no. 14, pp. 2364-2366, Jul. 2010, ISSN: 1539-4794. DOI: 10 . 1364/OL . 35 . Q02364.
[16] S. Zaske, D.-H. Lee, and C. Becher, “Green-pumped cw singly resonant optical parametric oscillator based on MgO: PPLN with frequency stabilization to an atomic resonance,” Applied Physics B, vol. 98, no. 4, pp. 729-735, Mar. 2010, ISSN: 1432-0649. DoI: 10.1007/s00340-009-3871-7.
[17] Luis Ledezma et al., Octave-spanning tunable infrared parametric oscillators in nanophotonics. Sci. Adv. 9, eadf9711 (2023). DOI:10.1126/sciadv.adf9711
[18] Further information on this example can be found in Ledezma, Luis M. (2023) Towards Universal Integrated Laser Sources with Nonlinear Photonics. Dissertation (Ph.D.), California Institute of Technology. doi: 10.7907/ag5t-r511. https:/resolver.caltech.edu/CaltechTHESIS:05242023-033922764

### Process Steps

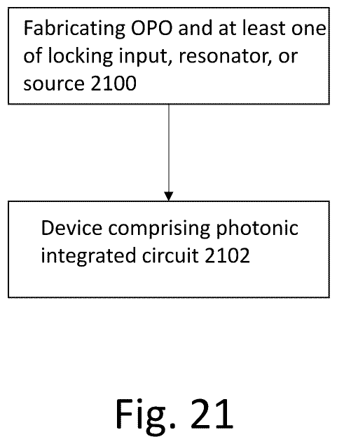

FIG. 21 is a flowchart illustrating method of making a device.

Block 2100 represents designing and fabricating (e.g., photolithographically patterning) the OPOs comprising one or more waveguides comprising the nonlinear material outputting a signal and an idler in response to a pump using a parametric nonlinear process. The waveguides each have a width and height of less than 5 micrometers. The nonlinear materials are phase matched and dispersion engineered to control appropriate group velocity mismatch (GVM) between pump and signal pulses so as to provide temporal overlap of the pump and signal pulses. In one or more examples, the, waveguides have the length in a range of 10 microns to 1 mm so that GVM difference is less than 1%. Example materials having the second order nonlinearity include, but are not limited to, lithium niobate, lithium tantalate, Potassium Titanyl Phosphate (KTP), aluminum nitride, gallium arsenide, indium phosphide, aluminum gallium arsenide, GaP, or InGaP. In one or more examples, the (e.g., nonlinear) material is patterned on a substrate to form a waveguides configured in the photonic integrated circuit. In one or more examples, the substrate comprises lithium niobate on silicon dioxide, and the waveguides are patterned in the lithium niobate (monolithic integration of the waveguides). Other components such as a laser, injection locking input, or auxiliary resonators can be patterned in the same substrate or on a different material substrate bonded to the substrate containing the OPO.

In one embodiment, the devices are fabricated using a commercial wafer with an x-cut, 700-nm-thick MgO-doped lithium niobate layer and a silicon oxide buffer layer.

We provide quasi-phase matching in a 5-mm-long region through periodic poling. The waveguides are patterned by e-beam lithography and dry etched with Ar+ plasma to a depth of 250 nm. All the OPOs have the same waveguide geometry obtained from dispersion engineering, with 2.3-μm-wide input and output waveguides that taper (through the adiabatic couplers) to 2.5-μm-wide waveguides inside the resonator. To maximize the spectral range covered on a single chip, we fabricated OPOs with poling periods ranging from 5.55 to 5.7 μm in 10-nm steps. We include a straight waveguide next to each OPO for calibration and quasi-phase matching verification. See Luis Ledezma et al., Octave-spanning tunable infrared parametric oscillators in nanophotonics. Sci. Adv. 9, eadf9711 (2023). DOI:10.1126/sciadv.adf9711, which reference is incorporated by reference herein.

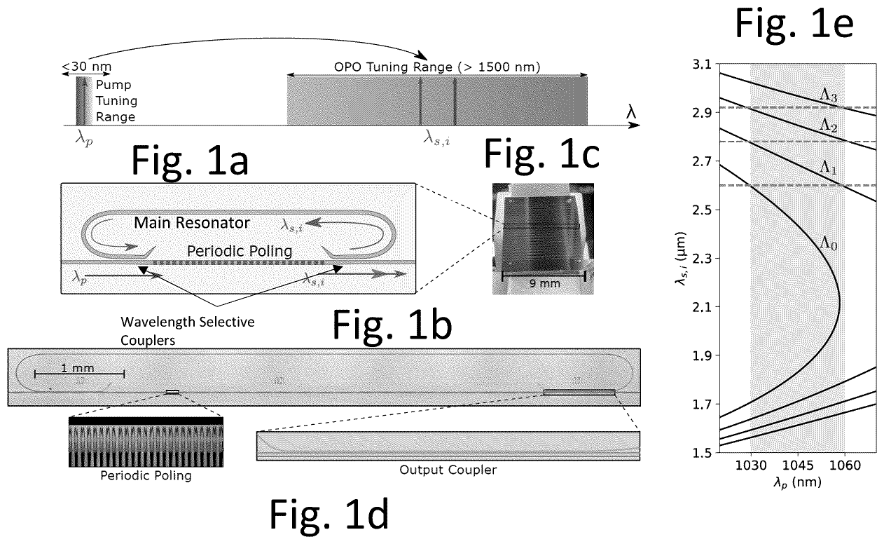

Block 2102 represents the end result, a device. The device can be embodied in many ways including, but not limited to, the following (referring also to FIGS. 1-20)
1. A device 300, 400, 600, 800, 900, 1000, 1100, 1200, 1300 comprising:
   a photonic integrated circuit 303 comprising:
      an optical parametric oscillator (OPO) 302 outputting at least one of a signal or an idler in response to a pump; and
   at least one of a source 700, 408 for the pump, an external injection locking input 502, or an auxiliary resonator 304 coupled to the OPO.
2. The device of embodiment 1, wherein the photonic integrated circuit further comprises an edge coupler 700, a grating coupler, or an evanescent coupler positioned to couple the source to the OPO.
3. The device of embodiment 1 or 2 wherein the source comprises a gain medium, such a semiconductor gain element 800, SOA and optionally a cavity 902 to form a laser comprising the gain medium.
4. The device of embodiment 3, wherein at least a portion of the laser cavity is in the photonic integrated circuit coupled to the gain medium, including a configuration in which the laser cavity is positioned to receive feedback 904 from the photonic integrated circuit into the laser cavity.
5. The device of any of the embodiments 2-4, wherein the OPO comprises an output coupler 906 coupled to output the feedback from the OPO to the gain medium and/or the laser cavity.
6. The device of any of the embodiments 3-5, wherein at least a portion of the OPO 908 is within the laser cavity.
7. The device of any of the embodiments 3-6, wherein the photonic integrated circuit comprises at least one of a reflector 904, 1010 positioned to reflect the feedback to the laser cavity, an auxiliary resonator 1002 coupled to the OPO, at least one OPO actuator 1004 coupled to the OPO for tuning the OPO, at least one auxiliary actuator 1006 coupled to the auxiliary resonator for tuning the auxiliary resonator, or a source actuator 1008, 908 coupled to the source for tuning the pump.
8. The device of embodiment 7, wherein the reflector 1010 is a tunable reflector configurable to tune a wavelength of the feedback controlling a wavelength of the pump outputted from the source.
9. The device of embodiment 7 or 8, further comprising:
   the laser cavity 902 comprising the reflector 1106 coupled to the OPO and the gain medium 1110, and
   the source actuator 1104 positioned between the reflector and the gain medium S0, 1110 and configurable to modulate the laser cavity so that the source comprises a mode-locked laser.
10. The device of embodiment 7 or 8, further comprising:
   the reflector comprising a wavelength tunable reflector 1108, and
   the source actuator 1004 positioned between the reflector and the gain medium 1110 and/or the source actuator is coupled to the reflector,
   and the actuators can modulate a wavelength of the source so that the source comprises a CW laser.
11. The device of any of the embodiments 3-10, wherein:
   the photonic integrated circuit comprises an auxiliary nonlinear region 1202 coupled between an output 1206 of the OPO and the gain medium 1204, and
   the auxiliary nonlinear region is configured to up convert a frequency of the signal and/or the idler to form feedback outputted to the gain medium and/or the laser cavity.
12. The device of embodiment 11, wherein the OPO is configurable to output a feedback to the laser cavity that self-injection-locks the pump.
13. The device of embodiment 11, wherein the OPO is configurable to output the feedback comprising multiple modes for mode-locking the source or provide the feedback for spectrally narrowing the pump.
14. The device of any of the embodiments embodiment 3-13, wherein the auxiliary resonator 304, 406, 408 is coupled in the photonic integrated circuit so as to at least:
   tune a frequency of the pump,
   filter the frequency of the pump, or
   self injection lock the pump of the OPO.
15. The device of any of the embodiments embodiment 1-14, wherein the auxiliary resonator 408, 406 is:
   resonant at a wavelength of the pump and is coupled to an additional parametric gain region or shares a parametric gain region 412 with the OPO, or
   tuned to filter or modulate a frequency of the modes in the OPO.
16. The device of any of the embodiments embodiment 1-14, wherein the auxiliary resonator comprises:
   a pump resonator 406 pumped by the pump 408 and having at least some overlapping modes with the OPO resonator so that at least some of the overlapping modes are enhanced and recycled in the pump resonator; and
   an electro-optical modulator 410 coupled to the pump resonator for locking the modes of the pump resonator to the modes of the pump.
17. The device of any of the embodiments embodiment 1-15, wherein the auxiliary resonator 304 is configured in the photonic integrated circuit so as to at least:
   tune a frequency of at least one of the signal or the idler,
   filter the frequency, or
   self injection lock at least one of the signal or the idler to the OPO.
18. The device of any of the embodiments 1-16, wherein the OPO comprises a main resonator 306 coupled to at least one parametric gain region 308 and the actuators comprise:
   one or more electro-optic modulators EOM, 410 coupled to at least one of the main resonator, the at least one parametric gain region, or the auxiliary resonator and actuatable to tune a gain and/or frequency of oscillation of pump, the signal, and/or the idler in the resonators, or
   a heater 310, 402 thermally coupled to the parametric gain region so that heat output is actuatable to tune a gain and/or center frequency of at least one of the pump, the idler, or the signal outputted from the parametric gain region.
19. The device of any of the embodiments 1-17 further comprising one or more of the external injection locking inputs 502 positioned to couple a seed signal configured for injection locking the signal and/or the idler.
20. The device of any of the embodiments embodiment 1-18, wherein the photonic integrated circuit further comprises additional OPOs 602 and a switch 604 for switching the pump 606 to different ones of the OPOs.
21. The device of any of the embodiments 1-19, further comprising a plurality of the auxiliary resonators 304 configurable to control a frequency of the signal and/or idler in a range such that the OPO can be operated free of mode-hops.
22. The device of any of the embodiments 1-20, wherein the OPO resonator 306 is coupled to one or more of the auxiliary resonators 304 having a different free spectral range, such that a combination of the modes of the main resonator and the auxiliary resonators selects a single mode or a set of modes that oscillate in the main resonators 306.
23. The device of any of the embodiments 3-21, further comprising a waveguide 704 coupling the gain medium to an input of the OPO, wherein the waveguide is configured to match a mode of the pump with a mode of the OPO.
24. The device of any of the embodiments embodiment 1-22, comprising a plurality of the OPOs comprising parametric gain regions 308 with different spectral responses, for instance through different quasi phase matching periods.
25. The device of any of the embodiments 1-23, wherein inputs and the outputs of the OPOs are coupled so that the signal and/or idler at one or more of the outputs are used as the pump at one or more of the inputs and parametric gain regions in the OPOs generate the signal and/or the idler in a wavelength range from visible to infrared by selecting an appropriate combinations of the inputs and outputs.
26. The device 600, 1200 of any of the embodiments 1-24, wherein the circuit further comprises at least one nonlinear section 1202 designed for up and/or down conversion of the signal, and/or the idler, through second-harmonic generation, and/or sum-frequency generation or difference-frequency generation, which can involve the pump or an auxiliary input to the circuit for the up and/or down conversion.
27. A device 300, 400, 500, 600, 700, 800, 900, 1000, 1100, 1200, 1300, comprising:
   a photonic integrated circuit 470 comprising:
      an optical parametric oscillator (OPO) comprising a main resonator 306 coupled to a parametric gain region 308 outputting a signal and an idler in response to a pump using a parametric nonlinear process; and
      at least one of a tuning circuit 304 or a mode-locking circuit 1106 coupled to the OPO.
28. The device of any of the embodiments 1-26, wherein the OPO comprises a waveguide 305.

### Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A device, comprising:
a photonic integrated circuit comprising:
an optical parametric oscillator (OPO) outputting at least one of a signal or an idler in response to a pump; and
at least one of a source for the pump, an external injection locking input, or an auxiliary resonator coupled to the OPO.

2. The device of claim 1, wherein the photonic integrated circuit further comprises an edge coupler, a grating coupler, or an evanescent coupler positioned to couple the source to the OPO.

3. The device of claim 1 wherein the source comprises a gain medium and/or a cavity to form a laser comprising the gain medium.

4. The device of claim 3, wherein at least a portion of the laser cavity is in the photonic integrated circuit coupled to the gain medium, including a configuration in which the laser cavity is positioned to receive feedback from the photonic integrated circuit into the laser cavity.

5. The device of claim 4, wherein the OPO comprises an output coupler coupled to output the feedback from the OPO to the gain medium and/or the laser cavity.

6. The device of claim 4, wherein at least a portion of the OPO is within the laser cavity.

7. The device of claim 4, wherein the photonic integrated circuit comprises at least one of a reflector positioned to reflect the feedback to the laser cavity, an auxiliary resonator coupled to the OPO, at least one OPO actuator coupled to the OPO for tuning the OPO, at least one auxiliary actuator coupled to the auxiliary resonator for tuning the auxiliary resonator, or a source actuator coupled to the source for tuning the pump.

8. The device of claim 7, wherein the reflector is a tunable reflector configurable to tune a wavelength of the feedback controlling a wavelength of the pump outputted from the source.

9. The device of claim 7, further comprising:
the laser cavity comprising the reflector coupled to the OPO and the gain medium, and
the source actuator positioned between the reflector and the gain medium and configurable to modulate the laser cavity so that the source comprises a mode-locked laser.

10. The device of claim 7, further comprising:
the reflector comprising a wavelength tunable reflector, and
the source actuator positioned between the reflector and the gain medium and/or the source actuator is coupled to the reflector,
and the actuators can modulate a wavelength of the source so that the source comprises a CW laser.

11. The device of claim 3, wherein:
the photonic integrated circuit comprises an auxiliary nonlinear region coupled between an output of the OPO and the gain medium, and
the auxiliary nonlinear region is configured to up convert a frequency of the signal and/or the idler to form feedback outputted to the gain medium and/or the laser cavity.

12. The device of claim 11, wherein the OPO is configurable to output a feedback to the laser cavity that self-injection-locks the pump.

13. The device of claim 11, wherein the OPO is configurable to output the feedback comprising multiple modes for mode-locking the source or provide the feedback for spectrally narrowing the pump.

14. The device of claim 3, wherein the auxiliary resonator is coupled in the photonic integrated circuit so as to at least:
tune a frequency of the pump,
filter the frequency of the pump, or
self injection lock the pump of the OPO.

15. The device of claim 1, wherein the auxiliary resonator is:
resonant at a wavelength of the pump and is coupled to an additional parametric gain region or shares a parametric gain region with the OPO, or
tuned to filter or modulate a frequency of the modes in the OPO.

16. The device of claim 1, wherein the auxiliary resonator comprises:
a pump resonator pumped by the pump and having at least some overlapping modes with the OPO resonator so that at least some of the overlapping modes are enhanced and recycled in the pump resonator; and
an electro-optical modulator coupled to the pump resonator for locking the modes of the pump resonator to the modes of the pump.

17. The device of claim 1, wherein the auxiliary resonator is configured in the photonic integrated circuit so as to at least:
tune a frequency of at least one of the signal or the idler,
filter the frequency, or
self injection lock at least one of the signal or the idler to the OPO.

18. The device of claim 1, wherein the OPO comprises a main resonator coupled to at least one parametric gain region and the actuators comprise:
one or more electro-optic modulators coupled to at least one of the main resonator, the at least one parametric gain region, or the auxiliary resonator and actuatable to tune a gain and/or frequency of oscillation of pump, the signal, and/or the idler in the resonators, or
a heater thermally coupled to the parametric gain region so that heat output is actuatable to tune a gain and/or center frequency of at least one of the pump, the idler, or the signal outputted from the parametric gain region.

19. The device of claim 1 further comprising one or more of the external injection locking inputs positioned to couple a seed signal configured for injection locking the signal and/or the idler.

20. The device of claim 1, wherein the photonic integrated circuit further comprises additional OPOs and a switch for switching the pump to different ones of the OPOs.

21. The device of claim 1, further comprising a plurality of the auxiliary resonators configurable to control a frequency of the signal and/or idler in a range such that the OPO can be operated free of mode-hops.

22. The device of claim 1, wherein the OPO resonator is coupled to one or more of the auxiliary resonators having a different free spectral range, such that a combination of the modes of the main resonator and the auxiliary resonators selects a single mode or a set of modes that oscillate in the main resonators.

23. The device of claim 3, further comprising a waveguide coupling the gain medium to an input of the OPO, wherein the waveguide is configured to match a mode of the pump with a mode of the OPO.

24. The device of claim 1, comprising a plurality of the OPOs comprising parametric gain regions with different spectral responses.

25. The device of claim 24, wherein inputs and the outputs of the OPOs are coupled so that the signal and/or idler at one or more of the outputs are used as the pump at one or more of the inputs and parametric gain regions in the OPOs generate the signal and/or the idler in a wavelength range from visible to infrared by selecting an appropriate combinations of the inputs and outputs.

26. The device of claim 1, wherein the circuit further comprises at least one nonlinear section designed for up and/or down conversion of the signal, and/or the idler, through second-harmonic generation, and/or sum-frequency generation or difference-frequency generation, which can involve the pump or an auxiliary input to the circuit for the up and/or down conversion.

27. A device, comprising:
a photonic integrated circuit comprising:
an optical parametric oscillator (OPO) comprising a main resonator coupled to a parametric gain region outputting a signal and an idler in response to a pump using a parametric nonlinear process; and
at least one of a tuning circuit or a mode-locking circuit coupled to the OPO.
